(19) United States
(12) Patent Application Publication
(10) Pub. No.: US 2025/0046662 A1
(43) Pub. Date: Feb. 6, 2025

(54) PACKAGING STRUCTURE, ELECTRONIC PACKAGE, AND METHODS FOR MANUFACTURING THE SAME

(71) Applicant: SILICONWARE PRECISION INDUSTRIES CO., LTD., Taichung City (TW)

(72) Inventor: Yung-Ta LI, Taichung City (TW)

(73) Assignee: SILICONWARE PRECISION INDUSTRIES CO., LTD., Taichung City (TW)

(21) Appl. No.: 18/396,976

(22) Filed: Dec. 27, 2023

(30) Foreign Application Priority Data
Jul. 31, 2023 (TW) 112128665

(51) Int. Cl. H01L 23/31; H01L 23/00

(52) U.S. Cl. CPC H01L 23/3121; H01L 24/32; H01L 2224/32225; H01L 2924/181

(57) ABSTRACT

A packaging structure is provided and includes: an electronic module; an encapsulation layer having a first surface and a second surface opposing the first surface and covering the electronic module; a protecting layer formed on the second surface of the encapsulation layer; and a heat conduction layer formed on the protecting layer. An electronic package including the packaging structure and methods for manufacturing the packaging structure and the electronic package are further provided.

### BACKGROUND

### 1. Technical Field

The present disclosure relates to a semiconductor device, and more particularly, to a packaging structure, an electronic package, and methods for manufacturing the packaging structure and the electronic package.

### 2. Description of Related Art

With the improvements on the requirements of functions and processing speed of electronic products, semiconductor chips as core components of electronic products need to have higher density electronic components and electronic circuits, which means that semiconductor chips will generate a greater amount of heat during operation.

In order to rapidly dissipate the heat to outside, as shown in FIG. 1, in the manufacturing method of a conventional semiconductor package 1, a semiconductor chip 11 is firstly disposed on a packaging substrate 10, and an encapsulation layer 12 is formed on the packaging substrate 10 to cover the semiconductor chip 11. Then, a heat dissipation element 14 (a heat sink or a heat spreader) is bonded onto the semiconductor chip 11 and the encapsulation layer 12 via a heat conduction layer 13, so that the heat generated from the semiconductor chip 11 can be dissipated via the heat conduction layer 13 and the heat dissipation element 14. That is, the heat conduction layer 13 is formed on a composite surface composed of the semiconductor chip 11 and the encapsulation layer 12, and the heat conduction layer 13 can be made of a thermal interface material (TIM) or a backside metal.

However, the thermal conductivity of the encapsulation layer 12 covering the semiconductor chip 11 is usually 0.8 W/mk, which indicates that the encapsulation layer 12 is made of a poor heat conduction material. Besides, there is a large difference in coefficient of thermal expansion (CTE) between the semiconductor chip 11 and the encapsulation layer 12, so that the heat cannot be transferred uniformly from the heat conduction layer 13 to the heat dissipation element 14, resulting in poor heat dissipation. In addition, during the manufacturing for the semiconductor package 1, the bonding force between the heat conduction layer 13 and the encapsulation layer 12 is poor since the surface of the encapsulation layer 12 is easy to absorb moisture, so the delamination issue is prone to occur.

Therefore, how to overcome the aforementioned drawbacks of the prior art has become an urgent issue to be addressed at present.

### SUMMARY

In view of the various shortcomings of the prior art, the present disclosure provides a packaging structure, the packaging structure comprises: an electronic module; an encapsulation layer having a first surface and a second surface opposing the first surface and covering the electronic module, wherein the electronic module is exposed from the second surface of the encapsulation layer; and a protecting layer formed on the electronic module and the second surface of the encapsulation layer.

The present disclosure also provides a method of manufacturing a packaging structure, the method comprises: disposing an electronic module and an encapsulation layer covering the electronic module on a carrier, wherein the encapsulation layer has a first surface and a second surface opposing the first surface, and the electronic module is exposed from the second surface of the encapsulation layer; forming a protecting layer on the second surface of the encapsulation layer and the electronic module; and removing the carrier.

In the aforementioned packaging structure and method, the protecting layer is made of silicon nitride.

In the aforementioned packaging structure and method, the present disclosure further comprises stacking a heat conduction element on the electronic module, wherein the heat conduction element is covered by the encapsulation layer, wherein the heat conduction element is exposed from the second surface of the encapsulation layer, and the heat conduction element and the second surface of the encapsulation layer are covered by the protecting layer.

In the aforementioned packaging structure and method, the electronic module is a semiconductor chip or a multi-chip package with functions of processing electrical signals.

In the aforementioned packaging structure and method, the first surface of the encapsulation layer is recessed with a plurality of voids, and the protecting layer is partially filled in the plurality of voids and has a plurality of recesses corresponding to the plurality of voids.

In the aforementioned packaging structure and method, the present disclosure further comprises forming a heat conduction layer on the protecting layer.

In the aforementioned packaging structure and method, a thermal conductivity of the protecting layer is greater than 4 W/cm-k.

The present disclosure further provides an electronic package, the electronic package comprises: a carrying structure; and the aforementioned packaging structure disposed on the carrying structure.

The present disclosure further provides a method of manufacturing an electronic package, the method comprises: providing a carrying structure; and disposing the packaging structure made from the aforementioned method on the carrying structure.

In the aforementioned electronic package and method, the present disclosure further comprises bonding a heat dissipation structure onto the packaging structure via the heat conduction layer.

As can be seen from the above, in the packaging structure, the electronic package and the manufacturing methods thereof according to the present disclosure, the overall uniformity of heat dissipation can be improved by the design of the protecting layer formed between the encapsulation layer and the heat conduction layer, and the protecting layer can prevent issues of poor bonding and easy delamination that are caused by moisture absorption due to direct exposure of pores on the surface of the encapsulation layer. Furthermore, the protecting layer can also enhance the bonding between the encapsulation layer and the heat conduction layer, and improve the heat conduction efficiency. In addition, the packaging structure, the electronic package and the manufacturing methods thereof of the present disclosure can be completed with existing manufacturing processes and equipment without spending a large amount of additional cost.

### BRIEF DESCRIPTION OF THE DRAWINGS

FIG. 1 is a schematic cross-sectional view of a conventional semiconductor package.

FIG. 2A-1, FIG. 2B, FIG. 2C and FIG. 2D are schematic cross-sectional views illustrating a method of manufacturing a packaging structure of the present disclosure.

FIG. 2A-2 is a schematic cross-sectional view illustrating another embodiment of an electronic module in a packaging structure of the present disclosure.

FIG. 2E to FIG. 2F are schematic cross-sectional views illustrating a method of manufacturing an electronic package of the present disclosure.

FIG. 3A to FIG. 3D are schematic cross-sectional views illustrating a method of manufacturing a packaging structure according to another embodiment of the present disclosure.

FIG. 3E and FIG. 3F are schematic cross-sectional views illustrating a method of manufacturing an electronic package according to another embodiment of the present disclosure.

### DETAILED DESCRIPTION

The following describes the implementation of the present disclosure with examples. Those familiar with the art can easily understand the other advantages and effects of the present disclosure from the content disclosed in this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” and the like are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

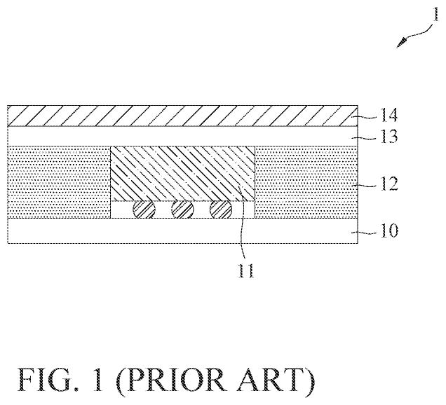

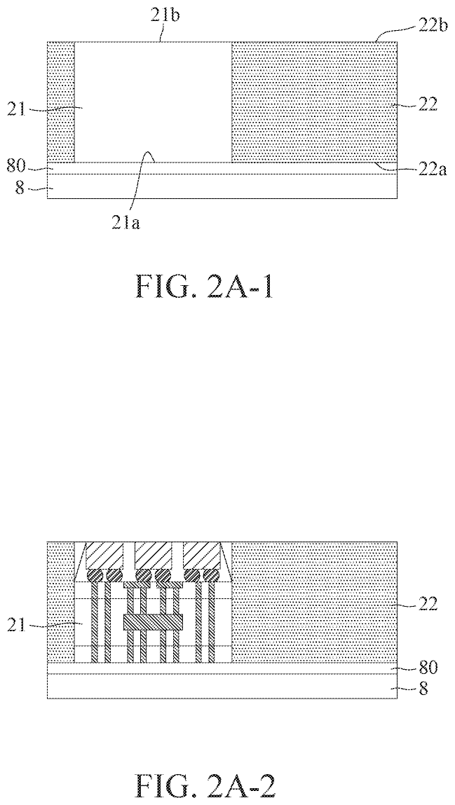

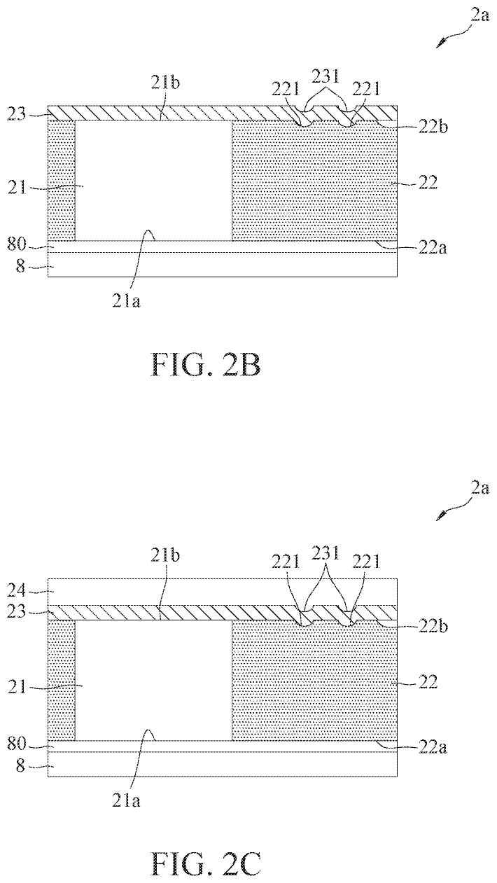

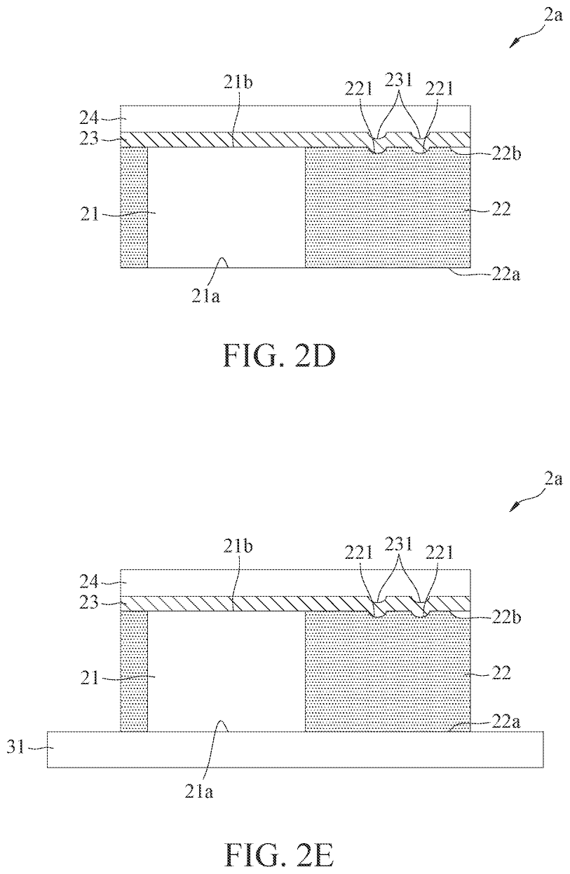

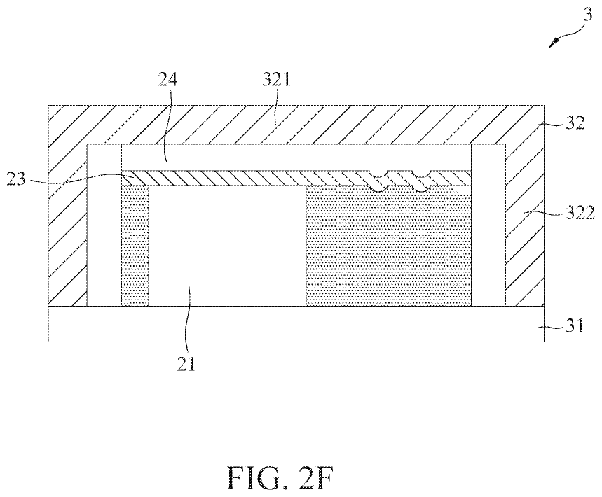

FIG. 2A-1, FIG. 2B, FIG. 2C and FIG. 2D are schematic cross-sectional views illustrating a method of manufacturing a packaging structure 2a of the present disclosure.

As shown in FIG. 2A-1, a carrier 8 is provided, and an electronic module 21 and an encapsulation layer 22 are disposed on the carrier 8.

In an embodiment, the carrier 8 is such as a plate body made of semiconductor material (e.g., silicon or glass), and a bonding layer 80 of a release film or of an adhesive film with other types is formed on the carrier 8 by for instance coating, wherein the bonding layer 80 is used as a sacrificial release layer.

The electronic module 21 can be an electronic element such as an active element, wherein the active element is for instance a semiconductor chip with functions of processing electrical signals. In an embodiment, the electronic module 21 is a semiconductor chip and has an active surface 21a and an inactive surface 21b opposing the active surface 21a, and the electronic module 21 is bonded onto the carrier 8 by its active surface 21a side.

In other embodiments, the electronic module 21 can be a multi-chip encapsulation/package as shown in FIG. 2A-2, but the present disclosure is not limited to as such.

The encapsulation layer 22 is formed on the carrier 8 to cover the electronic module 21. In an embodiment, the material forming the encapsulation layer 22 is an insulating material such as polyimide (PI), encapsulating colloid of epoxy resin, etc., and the encapsulation layer 22 can be formed by molding, lamination, or coating.

Besides, the encapsulation layer 22 has a first surface 22a and a second surface 22b opposing the first surface 22a, and the encapsulation layer 22 is bonded to the carrier 8 via the first surface 22a. In addition, the inactive surface 21b of the electronic module 21 is flush with the second surface 22b of the encapsulation layer 22, such that the inactive surface 21b of the electronic module 21 is exposed from the second surface 22b of the encapsulation layer 22. In an embodiment, the encapsulation layer 22 can firstly cover the inactive surface 21b of the electronic module 21, and then a leveling process such as grinding is performed to the encapsulation layer 22 to obtain the aspect of the encapsulation layer 22 shown in FIG. 2A-1.

As shown in FIG. 2B, a protecting layer 23 is formed on the second surface 22b of the encapsulation layer 22 and the inactive surface 21b of the electronic module 21, thereby obtaining the packaging structure 2a of the present disclosure.

In an embodiment, silicon nitride (SiN) can be formed as the protecting layer 23 via chemical vapor deposition (CVD), for example. The protecting layer 23 can prevent the surface of the encapsulation layer 22 from being directly exposed to cause moisture absorption, and can ensure that product defects due to delamination caused by water vapor will not occur in the subsequent processes, thus the protecting layer 23 can improve product reliability. Moreover, the protecting layer 23 can solve the conventional problem that the thermal expansion coefficient difference between the semiconductor chip and the encapsulation layer is too large, resulting in that the heat cannot be uniformly transferred to the heat dissipation element via the heat conduction layer, resulting in poor heat dissipation.

Furthermore, the second surface 22b of the encapsulation layer 22 may be recessed with a plurality of voids 221 with different dimensions, and the protecting layer 23 with a certain thickness is formed on the second surface 22b of the encapsulation layer 22 and the inactive surface 21b of the electronic module 21, thus part of the protecting layer 23 is filled in the plurality of voids 221, so that the protecting layer 23 has a plurality of recesses 231 corresponding to the plurality of voids 221.

In addition, the thermal conductivity of the protecting layer 23 is greater than 4 W/cm-k.

As shown in FIG. 2C, a heat conduction layer 24 can then be formed on the protecting layer 23. In an embodiment, the heat conduction layer 24 is partially filled in the plurality of recesses 231, and the top surface of the heat conduction layer 24 remains coplanar. In addition, the heat conduction layer 24 is made of a thermal interface material (TIM) or a backside metal such as a high heat conduction metal glue material, a solder material, or a metal material (which can be a multi-layer metal material).

As shown in FIG. 2D, the carrier 8 and the bonding layer 80 thereon are removed.

FIG. 2E to FIG. 2F are schematic cross-sectional views illustrating a method of manufacturing an electronic package 3 of the present disclosure.

As shown in FIG. 2E, the packaging structure 2a shown in FIG. 2D (or FIG. 2B) is disposed on a carrying structure 31.

The carrying structure 31 can be for example a circuit structure having a core layer (such as a hard substrate where a dielectric layer and a circuit layer formed on the dielectric layer are stacked on the core layer), a coreless circuit structure (such as a soft substrate formed by stacking a dielectric layer and a circuit layer formed on the dielectric layer), a through-silicon interposer (TSI) having conductive through-silicon vias (TSVs), or a board with other types. Furthermore, electrode pads of the active surface 21a of the electronic module 21 can be disposed on the carrying structure 31 in a flip-chip manner and electrically connected to the circuit layer within the carrying structure 31 via a plurality of conductive bumps such as solder balls, metal pillars, or the like; alternatively, the electronic module 21 can be directly in contact with the circuit layer of the carrying structure 31 (such as copper-to-copper heterogeneous bonding technique; copper-to-copper hybrid bonding). Therefore, the type and quantity of the electronic module 21 to be disposed on the carrying structure 31 can be determined first when manufacturing the packaging structure 2a so as to improve the electrical function thereof. Further, there are various ways for the electronic module 21 to be electrically connected to the carrying structure 31 and are not limited to the above.

As shown in FIG. 2F, a heat dissipation structure 32 is bonded onto the packaging structure 2a via the heat conduction layer 24, thereby obtaining the electronic package 3 of the present disclosure.

Moreover, in other embodiments, the heat conduction layer 24 may not be formed on the packaging structure 2a (as shown in FIG. 2B) before the heat dissipation structure 32 is being bonded to the packaging structure 2a, and the heat conduction layer 24 and the heat dissipation structure 32 are disposed on the packaging structure 2a in sequence.

The heat dissipation structure 32 has a heat dissipation sheet 321 and a plurality of supporting legs 322 extending downward from the edge of the heat dissipation sheet 321, wherein the lower side of the heat dissipation sheet 321 is bonded onto the packaging structure 2a via the heat conduction layer 24, and the supporting legs 322 are bonded onto the carrying structure 31 via such as glue to fix the heat dissipation structure 32. It can be understood that there are various types of the heat dissipation structure 32 and are not limited to the above.

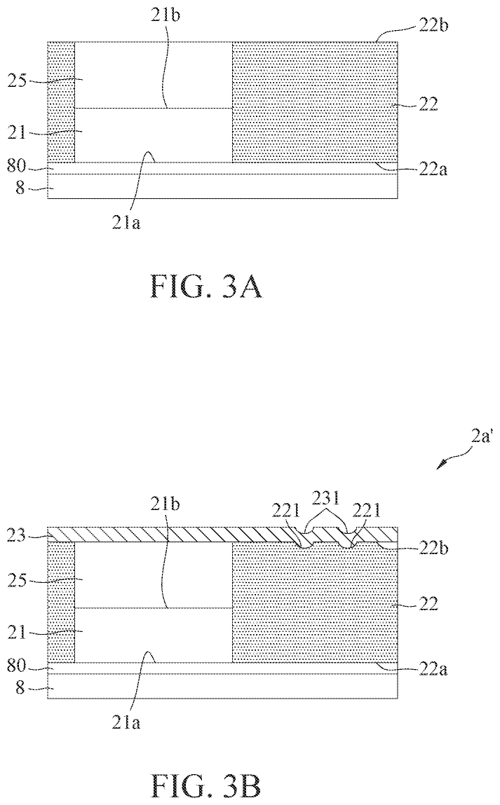

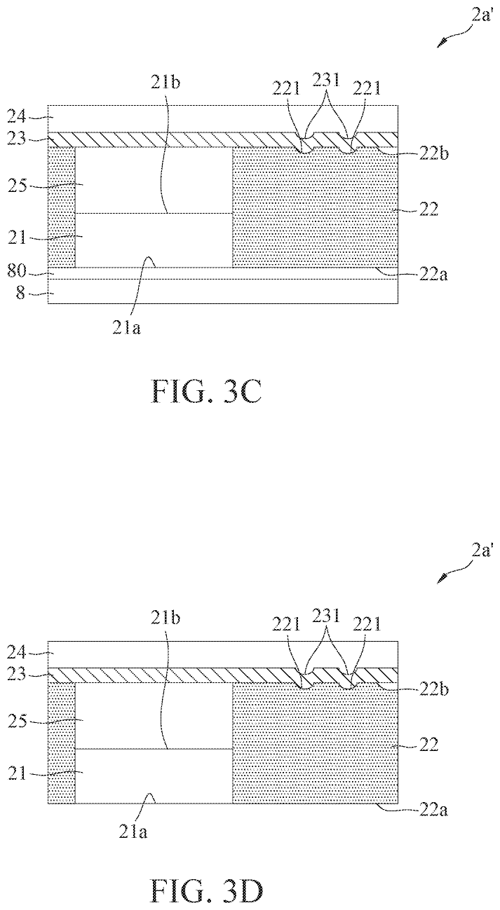

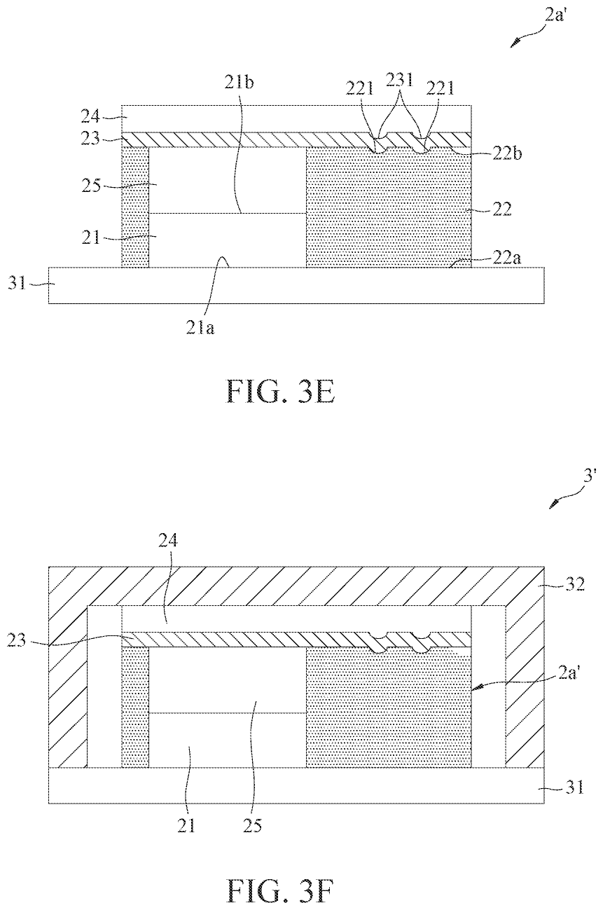

FIG. 3A to FIG. 3D are schematic cross-sectional views illustrating a method of manufacturing a packaging structure 2a′ according to another embodiment of the present disclosure. The difference between the embodiment of FIG. 3A to FIG. 3D and the embodiment of FIG. 2A-1 to FIG. 2D lies in the addition of a heat conduction element 25, and only the difference will be described below, and the same technical content will not be repeated.

As shown in FIG. 3A, the carrier 8 is provided. The electronic module 21 is disposed on the carrier 8, and the heat conduction element 25 is stacked on the electronic module 21, so that the encapsulation layer 22 covers the electronic module 21 and the heat conduction element 25.

In an embodiment, the top surface of the heat conduction element 25 is flush with the second surface 22b of the encapsulation layer 22, such that the heat conduction element 25 is exposed from the second surface 22b of the encapsulation layer 22.

Furthermore, the heat conduction element 25 can be a silicon chip such as a dummy die or a metal block.

As shown in FIG. 3B, the protecting layer 23 is formed on the second surface 22b of the encapsulation layer 22 and the heat conduction element 25, thereby obtaining the packaging structure 2a′ of the present disclosure. In an embodiment, silicon nitride (SiN) can be formed as the protecting layer 23 via chemical vapor deposition (CVD), for example. The protecting layer 23 can prevent the surface of the encapsulation layer 22 from being directly exposed to cause moisture absorption, and can ensure that product defects due to delamination caused by water vapor will not occur in the subsequent processes, thus the protecting layer 23 can improve product reliability. Moreover, the protecting layer 23 can solve the conventional problem that the thermal expansion coefficient difference between the semiconductor chip and the encapsulation layer is too large, resulting in that the heat cannot be uniformly transferred to the heat dissipation element via the heat conduction layer, resulting in poor heat dissipation.

Additionally, the protecting layer 23 with a certain thickness is formed on the second surface 22b of the encapsulation layer 22 and the heat conduction element 25, thus part of the protecting layer 23 is filled in the plurality of voids 221 recessed on the second surface 22b of the encapsulation layer 22, so that the protecting layer 23 has the plurality of recesses 231 corresponding to the plurality of voids 221.

As shown in FIG. 3C, the heat conduction layer 24 can then be formed on the protecting layer 23. In an embodiment, the heat conduction layer 24 is partially filled in the plurality of recesses 231, and the top surface of the heat conduction layer 24 remains coplanar.

As shown in FIG. 3D, the carrier 8 and the bonding layer 80 thereon are removed.

FIG. 3E and FIG. 3F are schematic cross-sectional views illustrating a method of manufacturing an electronic package 3′ according to another embodiment of the present disclosure.

As shown in FIG. 3E, the packaging structure 2a′ shown in FIG. 3D (or FIG. 3B) can be disposed on the carrying structure 31. And then, as shown in FIG. 3F, the heat dissipation structure 32 is bonded onto the packaging structure 2a′ via the heat conduction layer 24, thereby obtaining the electronic package 3′ of the present disclosure. Further, the heat conduction layer 24 may not be formed when manufacturing the packaging structure 2a′, and the heat conduction layer 24 and the heat dissipation structure 32 are disposed on the packaging structure 2a′ in sequence before the heat dissipation structure 32 is being bonded to the packaging structure 2a′.

The present disclosure further provides a packaging structure 2a, the packaging structure 2a comprises: an electronic module 21, an encapsulation layer 22, and a protecting layer 23.

The electronic module 21 can be an electronic element such as an active element, wherein the active element is for instance a semiconductor chip with functions of processing electrical signals. In an embodiment, the electronic module 21 is a semiconductor chip and has the active surface 21a and the inactive surface 21b opposing the active surface 21a. In other embodiments, the electronic module 21 can also be a multi-chip encapsulation/package.

The encapsulation layer 22 covers the electronic module 21 and has a first surface 22a and a second surface 22b opposing the first surface 22a. The inactive surface 21b of the electronic module 21 is flush with the second surface 22b of the encapsulation layer 22, such that the inactive surface 21b of the electronic module 21 is exposed from the second surface 22b of the encapsulation layer 22.

In an embodiment, the second surface 22b of the encapsulation layer 22 is recessed with a plurality of voids 221 with different dimensions.

The protecting layer 23 is formed on the second surface 22b of the encapsulation layer 22 and the inactive surface 21b of the electronic module 21. In an embodiment, silicon nitride (SiN) can be formed as the protecting layer 23 via chemical vapor deposition (CVD), for example.

In an embodiment, the protecting layer 23 has sufficient thickness, thus part of the protecting layer 23 is filled in the plurality of voids 221, so that the protecting layer 23 has a plurality of recesses 231 corresponding to the plurality of voids 221. Besides, the thermal conductivity of the protecting layer 23 is greater than 4 W/cm-k. In an embodiment, a heat conduction layer 24 can be formed on the protecting layer 23. In an embodiment, the heat conduction layer 24 is partially filled in the plurality of recesses 231, and the top surface of the heat conduction layer 24 remains coplanar. In addition, the heat conduction layer 24 is made of a thermal interface material (TIM) or a backside metal such as a high heat conduction metal glue material, a solder material, or a metal material (which can be a multi-layer metal material).

The present disclosure further provides a packaging structure 2a′, the packaging structure 2a′ comprises: an electronic module 21, an encapsulation layer 22, a protecting layer 23, and a heat conduction element 25. The difference between the packaging structure 2a′ and the packaging structure 2a lies in the addition of the heat conduction element 25, and only the difference will be described below, and the same technical content will not be repeated.

The heat conduction element 25 is stacked on the electronic module 21, so that the encapsulation layer 22 covers the electronic module 21 and the heat conduction element 25. In an embodiment, the heat conduction element 25 can be a silicon chip or a metal block.

In an embodiment, the top surface of the heat conduction element 25 is flush with a second surface 22b of the encapsulation layer 22, such that the heat conduction element 25 is exposed from the second surface 22b of the encapsulation layer 22. In an embodiment, the second surface 22b of the encapsulation layer 22 is recessed with a plurality of voids 221 with different dimensions.

The protecting layer 23 is formed on the second surface 22b of the encapsulation layer 22 and the heat conduction element 25. In an embodiment, the protecting layer 23 can be made of silicon nitride (SiN) formed by chemical vapor deposition (CVD).

In an embodiment, the protecting layer 23 has a certain thickness, thus part of the protecting layer 23 is filled in the plurality of voids 221, so that the protecting layer 23 has a plurality of recesses 231 corresponding to the plurality of voids 221. A heat conduction layer 24 is formed on the protecting layer 23 and is partially filled in the plurality of recesses 231, and the top surface of the heat conduction layer 24 remains coplanar.

The present disclosure further provides an electronic package 3, 3′, the packaging structure 2a, 2a′ is disposed on a carrying structure 31, and a heat dissipation structure 32 is bonded onto the packaging structure 2a, 2a′ via the heat conduction layer 24.

To sum up, in the packaging structure, the electronic package and the manufacturing methods thereof according to the present disclosure, the overall uniformity of heat dissipation can be improved by the design of the protecting layer formed between the encapsulation layer and the heat conduction layer, and the protecting layer can prevent issues of poor bonding and easy delamination that are caused by moisture absorption due to direct exposure of pores on the surface of the encapsulation layer. Furthermore, the protecting layer can also enhance the bonding between the encapsulation layer and the heat conduction layer, and improve the heat conduction efficiency. In addition, the packaging structure, the electronic package and the manufacturing methods thereof of the present disclosure can be completed with existing manufacturing processes and equipment without spending a large amount of additional cost.

The above embodiments are set forth to illustrate the principles of the present disclosure and the effects thereof, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. A packaging structure, comprising:
an electronic module;
an encapsulation layer having a first surface and a second surface opposing the first surface and covering the electronic module, wherein the electronic module is exposed from the second surface of the encapsulation layer; and
a protecting layer formed on the electronic module and the second surface of the encapsulation layer.

2. The packaging structure of claim 1, wherein the protecting layer is made of silicon nitride.

3. The packaging structure of claim 1, further comprising a heat conduction element stacked on the electronic module and covered by the encapsulation layer, wherein the heat conduction element is exposed from the second surface of the encapsulation layer, and the heat conduction element and the second surface of the encapsulation layer are covered by the protecting layer.

4. The packaging structure of claim 1, wherein the electronic module is a semiconductor chip or a multi-chip package.

5. The packaging structure of claim 1, wherein the first surface of the encapsulation layer is recessed with a plurality of voids, and the protecting layer is partially filled in the plurality of voids and has a plurality of recesses corresponding to the plurality of voids.

6. The packaging structure of claim 1, further comprising a heat conduction layer formed on the protecting layer.

7. The packaging structure of claim 1, wherein a thermal conductivity of the protecting layer is greater than 4 W/cm-k.

8. An electronic package, comprising:
a carrying structure; and
the packaging structure of claim 1, the packaging structure disposed on the carrying structure.

9. The electronic package of claim 8, further comprising a heat dissipation structure bonded onto the packaging structure.

10. An electronic package, comprising:
a carrying structure; and
the packaging structure of claim 2, the packaging structure disposed on the carrying structure.

11. The electronic package of claim 10, further comprising a heat dissipation structure bonded onto the packaging structure.

12. An electronic package, comprising:
a carrying structure; and
the packaging structure of claim 3, the packaging structure disposed on the carrying structure.

13. The electronic package of claim 12, further comprising a heat dissipation structure bonded onto the packaging structure.

14. An electronic package, comprising:
a carrying structure; and
the packaging structure of claim 4, the packaging structure disposed on the carrying structure.

15. The electronic package of claim 14, further comprising a heat dissipation structure bonded onto the packaging structure.

16. An electronic package, comprising:
a carrying structure; and
the packaging structure of claim 5, the packaging structure disposed on the carrying structure.

17. The electronic package of claim 16, further comprising a heat dissipation structure bonded onto the packaging structure.

18. An electronic package, comprising:
a carrying structure; and
the packaging structure of claim 6, the packaging structure disposed on the carrying structure.

19. The electronic package of claim 18, further comprising a heat dissipation structure bonded onto the packaging structure.

20. An electronic package, comprising:
a carrying structure; and
the packaging structure of claim 7, the packaging structure disposed on the carrying structure.

21. The electronic package of claim 20, further comprising a heat dissipation structure bonded onto the packaging structure.

22. A method of manufacturing a packaging structure, comprising:
disposing an electronic module and an encapsulation layer covering the electronic module on a carrier, wherein the encapsulation layer has a first surface and a second surface opposing the first surface, and the electronic module is exposed from the second surface of the encapsulation layer;
forming a protecting layer on the second surface of the encapsulation layer and the electronic module; and
removing the carrier.

23. The method of claim 22, wherein the protecting layer is made of silicon nitride.

24. The method of claim 22, further comprising stacking a heat conduction element on the electronic module, wherein the heat conduction element is covered by the encapsulation layer, wherein the heat conduction element is exposed from the second surface of the encapsulation layer, and the heat conduction element and the second surface of the encapsulation layer are covered by the protecting layer.

25. The method of claim 22, wherein the electronic module is a semiconductor chip or a multi-chip package.

26. The method of claim 22, wherein the first surface of the encapsulation layer is recessed with a plurality of voids, and the protecting layer is partially filled in the plurality of voids and has a plurality of recesses corresponding to the plurality of voids.

27. The method of claim 22, further comprising forming a heat conduction layer on the protecting layer.

28. The method of claim 22, wherein a thermal conductivity of the protecting layer is greater than 4 W/cm-k.

29. A method of manufacturing an electronic package, comprising:
providing a carrying structure; and
disposing the packaging structure made from the method of claim 22 on the carrying structure.

30. The method of claim 29, further comprising bonding a heat dissipation structure onto the packaging structure.

31. A method of manufacturing an electronic package, comprising:
providing a carrying structure; and
disposing the packaging structure made from the method of claim 23 on the carrying structure.

32. The method of claim 31, further comprising bonding a heat dissipation structure onto the packaging structure.

33. A method of manufacturing an electronic package, comprising:
providing a carrying structure; and
disposing the packaging structure made from the method of claim 24 on the carrying structure.

34. The method of claim 33, further comprising bonding a heat dissipation structure onto the packaging structure.

35. A method of manufacturing an electronic package, comprising:
providing a carrying structure; and
disposing the packaging structure made from the method of claim 25 on the carrying structure.

36. The method of claim 35, further comprising bonding a heat dissipation structure onto the packaging structure.

37. A method of manufacturing an electronic package, comprising:
providing a carrying structure; and
disposing the packaging structure made from the method of claim 26 on the carrying structure.

38. The method of claim 37, further comprising bonding a heat dissipation structure onto the packaging structure.

39. A method of manufacturing an electronic package, comprising:
providing a carrying structure; and
disposing the packaging structure made from the method of claim 27 on the carrying structure.

40. The method of claim 39, further comprising bonding a heat dissipation structure onto the packaging structure.

41. A method of manufacturing an electronic package, comprising:
providing a carrying structure; and
disposing the packaging structure made from the method of claim 28 on the carrying structure.

42. The method of claim 41, further comprising bonding a heat dissipation structure onto the packaging structure.
